(19) United States
(12) Patent Application Publication
(10) Pub. No.: US 2019/0064059 A1
(43) Pub. Date: Feb. 28, 2019

(54) LASER CRYSTALLIZATION MEASURING APPARATUS AND METHOD

(71) Applicants: Samsung Display Co., Ltd., Yongin-si (KR); K-MAC, Daejeon (KR)

(72) Inventors: Yong Jun Park, Yongin-si (KR); Seung-Ho Han, Seoul (KR); Kyoung Su Kim, Daejeon (KR); Jin Seo, Osan-si (KR); Se Yoon Oh, Yongin-si (KR); Dong-Seop Lim, Daejeon (KR); Sung Hoon Yang, Seoul (KR); Jun-Yeong Choi, Daejeon (KR)

(21) Appl. No.: 16/058,545

(22) Filed: Aug. 8, 2018

(30) Foreign Application Priority Data
Aug. 24, 2017 (KR) 10-2017-0107314

(51) Int. Cl. G01N 21/21; H01L 21/67; H01L 21/66

(52) U.S. Cl. CPC G01N 21/211; H01L 21/02675; H01L 22/12; H01L 21/67253

(57) ABSTRACT

A laser crystallization measuring apparatus including a spectrometer configured to measure actual data of a spectrum of an actual polycrystalline silicon layer crystallized by a laser crystallization device, and a simulation device that is connected to the spectrometer and is configured to determine simulation data of a spectrum of a virtual polycrystalline silicon layer according to a shape of a virtual protrusion formed in the virtual polycrystalline silicon layer, wherein a shape of an actual protrusion formed in the actual polycrystalline silicon layer is determined by using final data determined by selecting simulation data that is approximate to the actual data.

### CROSS-REFERENCE TO RELATED APPLICATION

This application claims priority to, and the benefit of, Korean Patent Application No. 10-2017-0107314, filed in the Korean Intellectual Property Office, on Aug. 24, 2017, the entire content of which is incorporated herein by reference.

### BACKGROUND

### 1. Field

Aspects of the present disclosure relate to a laser crystallization measuring apparatus and a method of using the same.

### 2. Description of the Related Art

In general, a method for crystallizing an amorphous silicon layer to a polycrystalline silicon layer includes solid phase crystallization (SPC), metal induced crystallization (MIC), metal induced lateral crystallization (MILC), excimer laser annealing (ELA), and the like. Particularly, the ELA is usually used to crystallize amorphous silicon to polycrystalline silicon by using laser beams in a process for manufacturing an organic light emitting diode display (OLED) or a liquid crystal display (LCD).

When the polycrystalline silicon layer is formed by the ELA, it is important to form large and uniform grains in the polycrystalline silicon layer.

The grains may be analyzed by breaking the polycrystalline silicon layer or by using a tester that directly checks the grain with the naked eye to thereby measure laser crystallization.

However, in this case, a measurement result of laser crystallization may be changed depending on an eye level of the tester or a proficiency level of the tester.

The above information disclosed in this Background section is only for enhancement of understanding of the background of the invention and therefore it may contain information that does not form the prior art.

### SUMMARY

Aspects of the present disclosure are directed to a laser crystallization measuring apparatus that can provide an iterative and consistent layer crystallization measurement result without generating a difference in the laser crystallization result depending on testers, and a method of using the same.

According to some embodiments of the present invention, there is provided a laser crystallization measuring apparatus including: a spectrometer configured to measure actual data of a spectrum of an actual polycrystalline silicon layer crystallized by a laser crystallization device; and a simulation device that is connected to the spectrometer and is configured to determine simulation data of a spectrum of a virtual polycrystalline silicon layer according to a shape of a virtual protrusion formed in the virtual polycrystalline silicon layer, wherein a shape of an actual protrusion formed in the actual polycrystalline silicon layer is determined by using final data determined by selecting simulation data that is approximate to the actual data.

In some embodiments, the shape of the virtual protrusion is determined by at least one selected from a height of the virtual protrusion, a gap between adjacent virtual protrusions, and a radius of a bottom side of the virtual protrusion.

In some embodiments, the spectrometer includes a spectroscopic ellipsometer.

In some embodiments, actual data of a spectrum of the actual polycrystalline silicon layer is determined by a phase difference and amplitude of polarized waves measured by the spectrometer.

In some embodiments, the spectrum includes a transmittance spectrum or a reflectance spectrum.

According to some embodiments of the present invention, there is provided a method for measuring laser crystallization, the method including: measuring actual data of a spectrum of an actual polycrystalline silicon layer crystallized by a laser crystallization device by using a spectrometer; measuring simulation data of a spectrum of a virtual polycrystalline silicon layer according to a shape of a virtual protrusion formed in the virtual polycrystalline silicon layer by using a simulation device; determining final data by selecting simulation data that is approximate to the actual data; and determining a shape of an actual protrusion formed in the actual polycrystalline silicon layer by using the final data.

In some embodiments, the shape of the virtual protrusion is determined by at least one selected from a height of the virtual protrusion, a gap between adjacent virtual protrusions, and a radius of a bottom side of the virtual protrusion.

In some embodiments, the spectrometer includes a spectroscopic ellipsometer.

In some embodiments, actual data of a spectrum of the actual polycrystalline silicon layer is determined by using a phase difference and amplitude of polarized waves, measured by the spectrometer.

In some embodiments, the spectrum includes a transmittance spectrum or a reflectance spectrum.

### BRIEF DESCRIPTION OF THE DRAWINGS

FIG. 1A is a schematic view of a laser crystallization measuring apparatus according to an exemplary embodiment of the present disclosure.

FIG. 1B is a cross-sectional view of an actual substrate and polycrystalline silicon layer formed thereon, according to an exemplary embodiment of the present disclosure.

FIG. 1C is a cross-sectional view of a virtual substrate and virtual polycrystalline silicon layer formed thereon, according to an exemplary embodiment of the present disclosure.

FIG. 2 is a flow diagram of a method for measuring laser crystallization by using the laser crystallization measuring apparatus according to the exemplary embodiment of the present disclosure.

FIG. 3 is an actual data graph of a phase difference according to a wavelength of a polycrystalline silicon layer measured by using a spectrometer of the laser crystallization measuring apparatus according to the exemplary embodiment of the present disclosure.

FIG. 4 is an actual data graph of amplitude according to a wavelength of a polycrystalline silicon layer measured by using a spectrometer of the laser crystallization measuring apparatus according to the exemplary embodiment of the present disclosure.

FIG. 5 is an actual data graph of a transmittance spectrum according to a wavelength of a polycrystalline silicon layer measured by using a spectrometer of the laser crystallization measuring apparatus according to the exemplary embodiment of the present disclosure.

FIG. 6 is a simulated data graph of a transmittance spectrum according to a height variation of a protrusion in a simulation device of the laser crystallization measuring apparatus according to the exemplary embodiment of the present disclosure.

FIG. 7 is a simulated data graph of a transmittance spectrum according to a radius variation of a protrusion in a simulation device of the laser crystallization measuring apparatus according to the exemplary embodiment of the present disclosure.

### DETAILED DESCRIPTION

Hereinafter, exemplary embodiments of the present disclosure will be described in more detail with reference to the accompanying drawings. As those skilled in the art would actualize, the described embodiments may be modified in various suitable ways, all without departing from the spirit or scope of the present disclosure.

The drawings and description are to be regarded as illustrative in nature and not restrictive. Like reference numerals designate like elements throughout the specification.

In addition, the size and thickness of each configuration shown in the drawings are arbitrarily shown for better understanding and ease of description, but the present disclosure is not limited thereto.

Hereinafter, a laser crystallization measuring apparatus according to an exemplary embodiment will be described in detail with reference to the accompanying drawings.

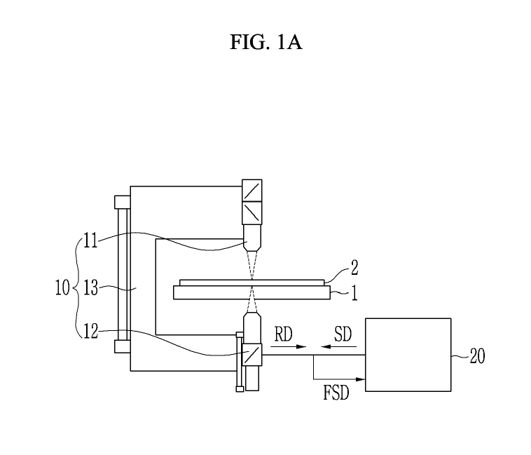

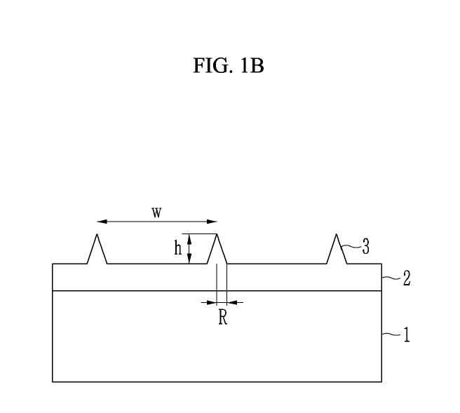

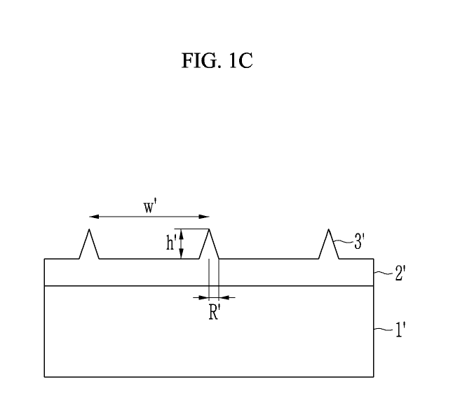

FIG. 1A schematically illustrates a laser crystallization measuring apparatus according to an exemplary embodiment of the present disclosure. FIG. 1B is a cross-sectional view of an actual substrate and polycrystalline silicon layer formed thereon, according to an exemplary embodiment of the present disclosure. FIG. 1C is a cross-sectional view of a virtual substrate and virtual polycrystalline silicon layer formed thereon, according to an exemplary embodiment of the present disclosure.

As shown in FIG. 1, a laser crystallization measuring apparatus according to an exemplary embodiment includes a spectrometer 10 and a simulation device 20 connected to the spectrometer 10.

A substrate 1 where an actual polycrystalline silicon layer 2 is formed is disposed in the spectrometer 10. The actual polycrystalline silicon layer 2 may be crystallized by a laser crystallization apparatus using an excimer laser annealing (ELA) method.

The spectrometer 10 may include a spectroscopic ellipsometer. The spectroscopic ellipsometer may measure a transmittance spectrum or a reflectance spectrum according to a wavelength by detecting a phase difference and amplitude variation of a P wave and an S wave, which are polarized waves incident on the actual polycrystalline silicon layer 2. Hereinafter, the transmittance spectrum will be described for better comprehension and ease of description, and the same description may be applied to the reflectance spectrum.

The spectrometer 10 may include a light source 11 that irradiates light to the actual polycrystalline silicon layer 2, a detector 12 that detects light passed through the actual polycrystalline silicon layer 2, and a frame 13 that supports the light source 11 and the detector 120 by connecting them to each other. Such a spectrometer 10 may measure actual data RD of transmittance according to a wavelength of the actual polycrystalline silicon layer 2. A structure of the spectrometer 10 is not limited to the above-described structure, and any structure that can measure transmittance according to a wavelength of the actual polycrystalline silicon layer 2 is applicable.

In addition, in FIG. 1, a structure of the spectrometer 10 for measurement of transmittance is illustrated, but this is not restrictive. Any spectrometer 10 having a structure for reflectance measurement is applicable. For example, the detector 12 may be disposed in the same direction as the light source 11 with reference to the substrate 1 so as to detect reflected light.

The simulation device 20 determines (e.g., calculates or measures) simulation data SD of the transmittance spectrum of a virtual (e.g., simulated) polycrystalline silicon layer 2′ according to a shape of a virtual protrusion 3′ formed in the virtual polycrystalline silicon layer 2′.

The simulation device 20 determines final data FSD by selecting simulation data SD that is approximate to (i.e., is closest to or diverts least away from) the actual data RD measured by using the spectrometer 10 among a plurality of pieces of simulation data SD.

In addition, a shape of an actual protrusion 3 formed in the actual polycrystalline silicon layer 2 is analogized by using the final data FSD. That is, the shape of the actual protrusion 3 determined by a height h of the actual protrusion 3, a gap W between adjacent actual protrusions 3, and a radius R of a bottom side (e.g., a bottom portion) of the actual protrusion 3 can be determined.

The actual protrusion 3 is formed at an interface of grains of the actual polycrystalline silicon layer 2, and therefore laser crystallization can be measured by using the shape of the actual protrusion 3. That is, as the actual protrusions 3 have a uniform height h, it can be determined that the laser crystallization is high, and as the adjacent actual protrusions 3 have a constant gap W, it can be determined that the laser crystallization is high. In addition, as the bottom sides (e.g., bottom portions) of the actual protrusions 3 have a constant radius R (i.e., as the protrusions 3 have a substantially conical shape), it can be determined that the laser crystallization is high.

As described, actual data RD of the transmittance spectrum of the polycrystalline silicon layer 2 measured by the spectrometer 10 and simulation data SD of the virtual polycrystalline silicon layer 2′ simulated by the simulation device 20 are compared to determine (e.g., measure) a shape of the actual protrusion 3 of the actual polycrystalline silicon layer 2. Thus, laser crystallization of the actual polycrystalline silicon layer 2 can be measured by analyzing the determined (e.g., measured) shape of the actual protrusion 3, and accordingly, the laser crystallization of the actual polycrystalline silicon layer 2 can be iteratively and consistently measured.

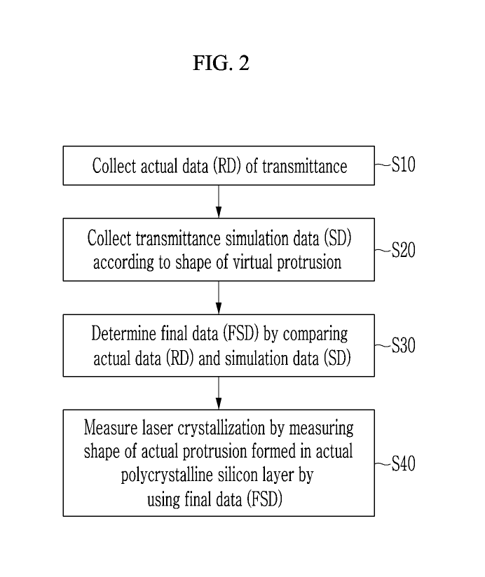

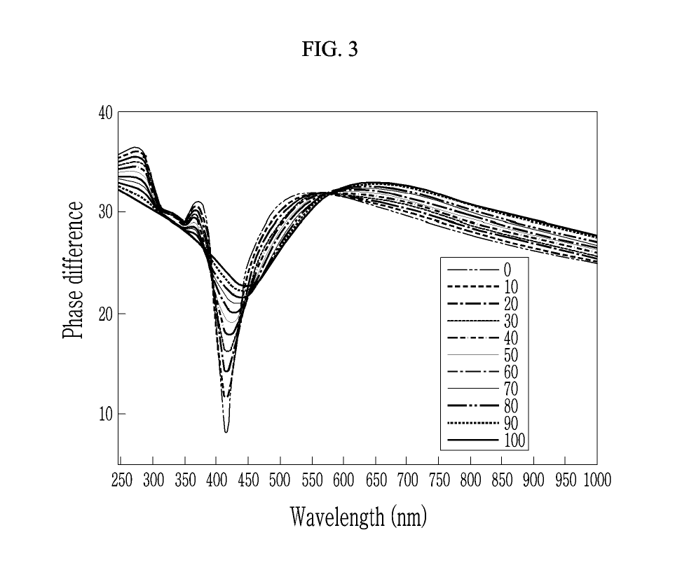

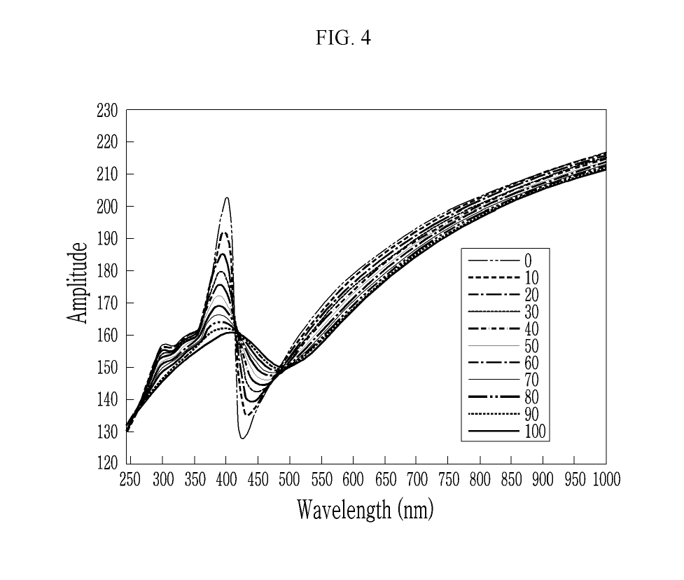

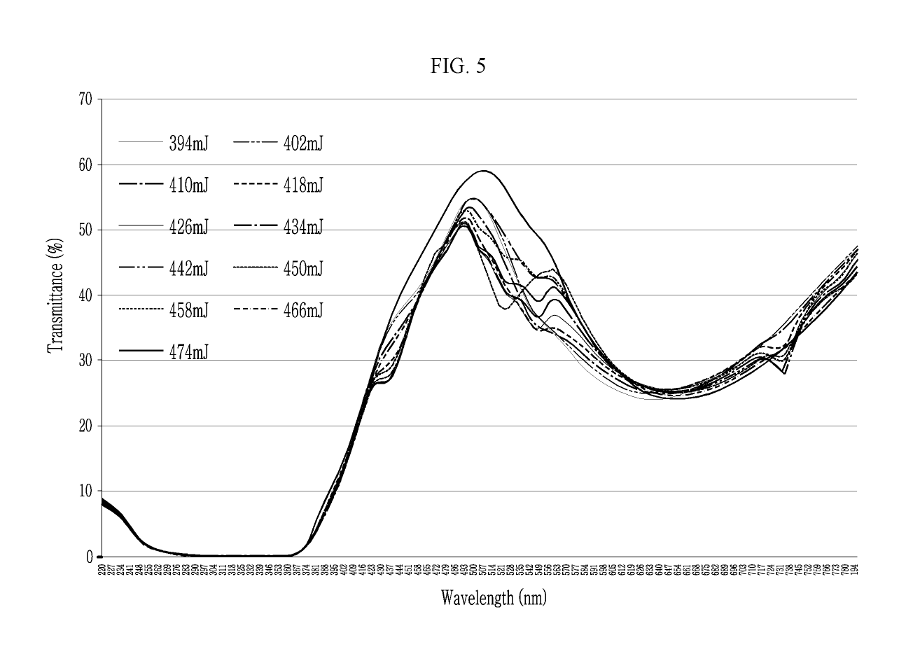

FIG. 2 is a flowchart of a method for measuring laser crystallization by using the laser crystallization measuring apparatus according to the exemplary embodiment of the present disclosure. FIG. 3 is an actual data graph of a phase difference according to wavelengths of the polycrystalline silicon layer measured by the spectrometer according to the exemplary embodiment of the present disclosure. FIG. 4 is an actual data graph of amplitude according to wavelengths of the polycrystalline silicon layer measured by using the spectrometer of the laser crystallization measuring apparatus according to the exemplary embodiment of the present disclosure. FIG. 5 is an actual data graph of a transmittance spectrum according to wavelengths of the polycrystalline silicon layer measured by using the spectrometer of the laser crystallization measuring apparatus according to the exemplary embodiment of the present disclosure.

As shown in FIG. 2, a laser crystallization measuring method according to the exemplary embodiment includes measuring actual data RD of a transmittance spectrum according to a wavelength of the actual polycrystalline silicon layer 2 by using the spectrometer (S10). That is, the actual data graphs of a phase difference and amplitude according to the wavelength shown in FIG. 3 and FIG. 4 are made by using the spectrometer 10 shown in FIG. 1.

A P wave and an S wave, which are polarized waves irradiated from the light source 11 of the spectrometer 10, are incident on the actual polycrystalline silicon layer 2 and are detected by the detector 12. In this case, the transmittance spectrum according to wavelengths can be measured by determining a phase difference and amplitude variation of the P wave and the S wave.

In addition, an actual data graph of transmittance spectrum according to the waves shown in FIG. 5 is made by using the actual data graph of the phase different and amplitude according to waves shown in FIG. 3 and FIG. 4. In this case, an actual data graph of various transmittance spectrums is made according to an energy level of the laser beam irradiated to the actual polycrystalline silicon layer 2.

Next, as shown in FIG. 2, simulation data SD of the transmittance spectrum of the virtual polycrystalline silicon layer 2′ is measured by using the simulation device 20 (S20).

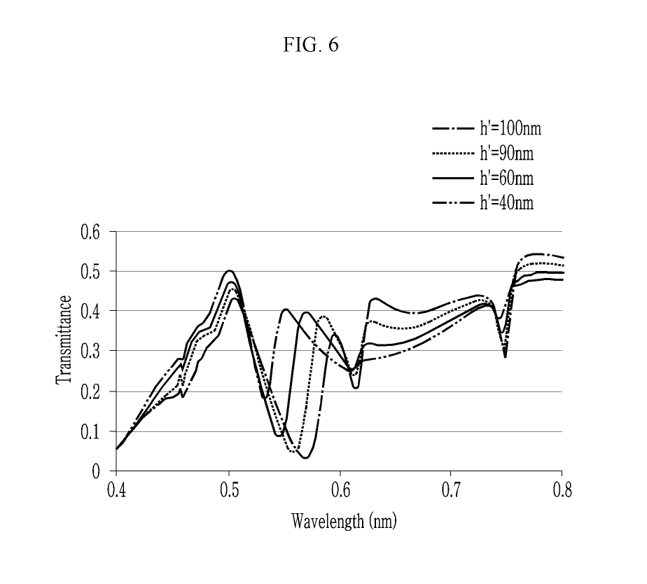

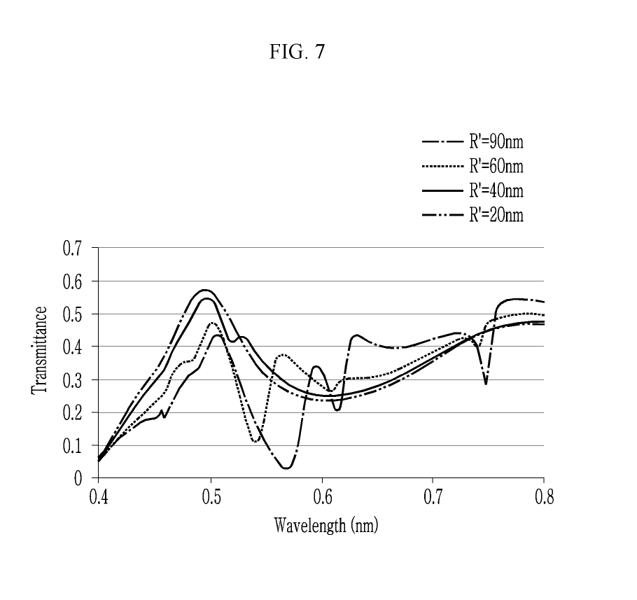

FIG. 6 is a virtual data graph of a transmittance spectrum according to a height variation of a virtual protrusion in the simulation device of the laser crystallization measuring apparatus according to the exemplary embodiment of the present disclosure. FIG. 7 is a virtual data graph of the transmittance spectrum according to a radius variation of the virtual protrusion in the simulation device of the laser crystallization measuring apparatus according to the exemplary embodiment of the present disclosure.

As shown in FIG. 1, a shape of a virtual protrusion 3′ formed in the virtual polycrystalline silicon layer 2′ on a virtual substrate 1′ in the simulation device 20 can be adjusted. The shape of the virtual protrusion 3′ may be determined by a height h′ of the virtual protrusion 3′, a gap W′ between adjacent virtual protrusions 3′, and a radius R′ of the bottom side of the virtual protrusion 3′.

In FIG. 5, the virtual protrusion 3′ has a conical shape; however, embodiments of the present disclosure are not limited thereto, and the virtual protrusion 3′ may have various suitable shapes.

In addition, the shape of the virtual protrusion is determined by the height of the virtual protrusion, the gap between adjacent virtual protrusions, and the radius of the bottom side of the virtual protrusion in the present exemplary embodiment; however, embodiments of the present disclosure are not limited thereto.

As shown in FIG. 6, transmittance spectrum according to wavelengths can be changed by adjusting the height h′ of the virtual protrusion 3′. FIG. 6 shows a transmittance spectrum graph according to wavelengths when the heights h′ of the virtual protrusion 3′ are 40 nm, 60 nm, 90 nm, and 100 nm, respectively.

In addition, as shown in FIG. 7, the transmittance spectrum according to wavelengths can be changed by adjusting each of the radii R′ of the bottom side of the virtual protrusions 3′. FIG. 7 shows a transmittance spectrum graph according to wavelengths when the radii R′ of each of the bottom sides of the virtual protrusions 3′ are 20 nm, 40 nm, 60 nm, and 90 nm, respectively.

As described, simulation data SD of the transmittance spectrum according to wavelengths can be made by adjusting the shape of the virtual protrusion 3′ formed in the virtual polycrystalline silicon layer 2′ in the simulation device 20.

Next, as shown in FIG. 2, final data FSD that is approximate to (i.e., is closest to or diverts least away from) the actual data RD is determined among the plurality of pieces of simulation data SD (S30). The final data FSD may be simulation data SD that is closest to the actual data RD of the transmittance spectrum according to wavelengths.

Next, as shown in FIG. 2, a shape of the actual protrusion 3 formed in the actual polycrystalline silicon layer 2 can be analogized by using the final data FSD (S40). That is, the shape of the actual protrusion 3 determined by a height h of the actual protrusion 3, a gap between adjacent actual protrusions 3, and a radius R of the bottom side of the actual protrusion 3.

In addition, laser crystallization can be measured by using the shape of the actual protrusion 3. That is, it can be determined that the laser crystallization can be high as the actual protrusion 3 has a uniform height h, and the laser crystallization can be high as the adjacent actual protrusions 3 have a constant gap W. Further, it can be determined that as the bottom side of the actual protrusion 3 has a constant radius R, the laser crystallization becomes high.

As described, the actual data RD of the transmittance spectrum of the actual polycrystalline silicon layer 2 measured by the spectrometer 10 and the simulation data SD of the virtual polycrystalline silicon layer 2′ simulated by the simulation device 20 are compared to determine (e.g., measure) the shape of the actual protrusion 3 of the actual polycrystalline silicon layer 2. Thus, because the laser crystallization of the actual polycrystalline silicon layer 2 can be measured by analyzing the measured shape of the actual protrusion 3, the laser crystallization of the actual polycrystalline silicon layer 2 can be iteratively and consistently measured.

It will also be understood that when a layer is referred to as being “between” two layers, it can be the only layer between the two layers, or one or more intervening layers may also be present.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art. Further, a specific quantity or range recited in this written description or the claims may also encompass the inherent variations in measured or calculated values that would be recognized by those of ordinary skill in the art.

As used herein, the terms “use,” “using,” and “used” may be considered synonymous with the terms “utilize,” “utilizing,” and “utilized,” respectively.

The laser crystallization measuring apparatus and/or any other relevant devices or components, such as the spectrometer and the simulation device, according to embodiments of the present invention described herein may be implemented utilizing any suitable hardware, firmware (e.g. an application-specific integrated circuit), software, or a suitable combination of software, firmware, and hardware. For example, the various components of the laser crystallization measuring apparatus may be formed on one integrated circuit (IC) chip or on separate IC chips. Further, the various components of the laser crystallization measuring apparatus may be implemented on a flexible printed circuit film, a tape carrier package (TCP), a printed circuit board (PCB), or formed on a same substrate. Further, the various components of the laser crystallization measuring apparatus may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the exemplary embodiments of the present invention.

While this invention has been described in connection with what is presently considered to be practical exemplary embodiments, it is to be understood that the invention is not limited to the disclosed embodiments, and is intended to cover various suitable modifications and equivalent arrangements included within the spirit and scope of the invention as defined by the appended claims and equivalents thereof.

Description of symbols

| | |
|---|---|
| 1: substrate | 2: actual polycrystalline silicon layer |
| 3: actual protrusion | 3′: virtual protrusion |
| 10: spectrometer | 11: light source |
| 12: detector | 13: frame |
| 20: simulation device | h: height of actual protrusion |
| h′: height of virtual protrusion | W: gap between adjacent actual |
| | protrusions |

W′: gap between adjacent virtual protrusions
R: radius of bottom side of actual protrusion
R′: radius of bottom side of virtual protrusion

What is claimed is:

1. A laser crystallization measuring apparatus comprising:
a spectrometer configured to measure actual data of a spectrum of an actual polycrystalline silicon layer crystallized by a laser crystallization device; and
a simulation device that is connected to the spectrometer and is configured to determine simulation data of a spectrum of a virtual polycrystalline silicon layer according to a shape of a virtual protrusion formed in the virtual polycrystalline silicon layer,
wherein a shape of an actual protrusion formed in the actual polycrystalline silicon layer is determined by using final data determined by selecting simulation data that is approximate to the actual data.

2. The laser crystallization measuring apparatus of claim 1, wherein the shape of the virtual protrusion is determined by at least one selected from a height of the virtual protrusion, a gap between adjacent virtual protrusions, and a radius of a bottom side of the virtual protrusion.

3. The laser crystallization measuring apparatus of claim 1, wherein the spectrometer comprises a spectroscopic ellipsometer.

4. The laser crystallization measuring apparatus of claim 1, wherein actual data of a spectrum of the actual polycrystalline silicon layer is determined by a phase difference and amplitude of polarized waves measured by the spectrometer.

5. The laser crystallization measuring apparatus of claim 1, wherein the spectrum comprises a transmittance spectrum or a reflectance spectrum.

6. A method for measuring laser crystallization, the method comprising:
measuring actual data of a spectrum of an actual polycrystalline silicon layer crystallized by a laser crystallization device by using a spectrometer;
measuring simulation data of a spectrum of a virtual polycrystalline silicon layer according to a shape of a virtual protrusion formed in the virtual polycrystalline silicon layer by using a simulation device;
determining final data by selecting simulation data that is approximate to the actual data; and
determining a shape of an actual protrusion formed in the actual polycrystalline silicon layer by using the final data.

7. The method for measuring laser crystallization of claim 6, wherein the shape of the virtual protrusion is determined by at least one selected from a height of the virtual protrusion, a gap between adjacent virtual protrusions, and a radius of a bottom side of the virtual protrusion.

8. The method for measuring laser crystallization of claim 6, wherein the spectrometer comprises a spectroscopic ellipsometer.

9. The method for measuring laser crystallization of claim 6, wherein actual data of a spectrum of the actual polycrystalline silicon layer is determined by using a phase difference and amplitude of polarized waves, measured by the spectrometer.

10. The method for measuring laser crystallization of claim 6, wherein the spectrum comprises a transmittance spectrum or a reflectance spectrum.
